(19) United States
(12) Patent Application Publication
(10) Pub. No.: US 2020/0303249 A1
(43) Pub. Date: Sep. 24, 2020

(54) SEMICONDUCTOR PACKAGE, DIE ATTACH FILM, AND METHOD FOR MANUFACTURING DIE ATTACH FILM

(71) Applicants: Kabushiki Kaisha Toshiba, Tokyo (JP); Toshiba Electronic Devices & Storage Corporation, Tokyo (JP)

(72) Inventor: Hiroaki Kishi, Yokohama Kanagawa (JP)

(21) Appl. No.: 16/567,557

(22) Filed: Sep. 11, 2019

(30) Foreign Application Priority Data
Mar. 20, 2019 (JP) 2019-052326

(51) Int. Cl. H01L 21/768; H01L 23/532; H01L 23/495; H01L 23/00

(52) U.S. Cl. CPC H01L 21/76873; H01L 23/53228; H01L 2224/48247; H01L 24/83; H01L 23/49513

(57) ABSTRACT

A method for manufacturing a die attach film includes forming a plurality of posts on a support sheet. The method includes forming an adhesive layer between the posts. A thermal conductivity of the adhesive layer is lower than a thermal conductivity of the posts. The method includes removing the support sheet.

### CROSS-REFERENCE TO RELATED APPLICATIONS

This application is based upon and claims the benefit of priority from the prior Japanese Patent Application No. 2019-052326, filed on Mar. 20, 2019; the entire contents of which are incorporated herein by reference.

### FIELD

Embodiments relate to a semiconductor package, a die attach film, and method for manufacturing the die attach film.

### BACKGROUND

Conventionally, semiconductor packages have been developed in which a semiconductor chip is fixed to a leadframe by a die attach film (DAF); and the leadframe and the semiconductor chip are sealed with a resin member. Good heat dissipation of the semiconductor package is desirable when the heat generation amount of the semiconductor chip is large.

### BRIEF DESCRIPTION OF THE DRAWINGS

FIG. 1 is a cross-sectional view showing a semiconductor package according to a first embodiment;

FIG. 2 is a plan view showing the semiconductor package according to the first embodiment;

FIG. 3A is a perspective view showing a die attach film according to the first embodiment;

FIG. 3B is a cross-sectional view showing the die attach film according to the first embodiment;

FIG. 4 is a plan view showing a die attach film according to a first modification of the first embodiment;

FIG. 5A is a perspective view showing a die attach film according to a second modification of the first embodiment;

FIG. 5B is a plan view of the die attach film according to the second modification of the first embodiment;

FIG. 6 is a plan view showing a semiconductor package according to a third modification of the first embodiment;

FIG. 7 is a plan view showing a die attach film according to a fourth modification of the first embodiment;

FIG. 8A to FIG. 15B show a method for manufacturing a die attach film according to a second embodiment;

FIG. 16A to FIG. 21B show a method for manufacturing a die attach film according to a third embodiment;

FIGS. 22A to 22D and FIGS. 23A to 23D are cross-sectional views showing a method for manufacturing a die attach film according to a fourth embodiment;

FIGS. 24A to 24E are cross-sectional views showing a method for manufacturing a die attach film according to a fifth embodiment; and

FIGS. 25A to 25C show a method for manufacturing a semiconductor package according to a sixth embodiment.

### DETAILED DESCRIPTION

In general, according to one embodiment, a method is disclosed for manufacturing a die attach film. The method includes forming a plurality of posts on a support sheet. The method includes forming an adhesive layer between the posts. A thermal conductivity of the adhesive layer is lower than a thermal conductivity of the posts. The method includes removing the support sheet.

In general, according to one embodiment, a die attach film includes an adhesive layer and a plurality of posts. The plurality of posts is provided inside the adhesive layer and exposed at a first surface of the adhesive layer. A thermal conductivity of the plurality of posts is higher than a thermal conductivity of the adhesive layer.

In general, according to one embodiment, a semiconductor package includes a leadframe, a semiconductor chip, the die attach film, and a resin member. The die attach film contacts the leadframe and the semiconductor chip and fixes the semiconductor chip to the leadframe. The resin member covers the die attach film, the semiconductor chip, and at least a portion of the leadframe.

### First Embodiment

A first embodiment will now be described.

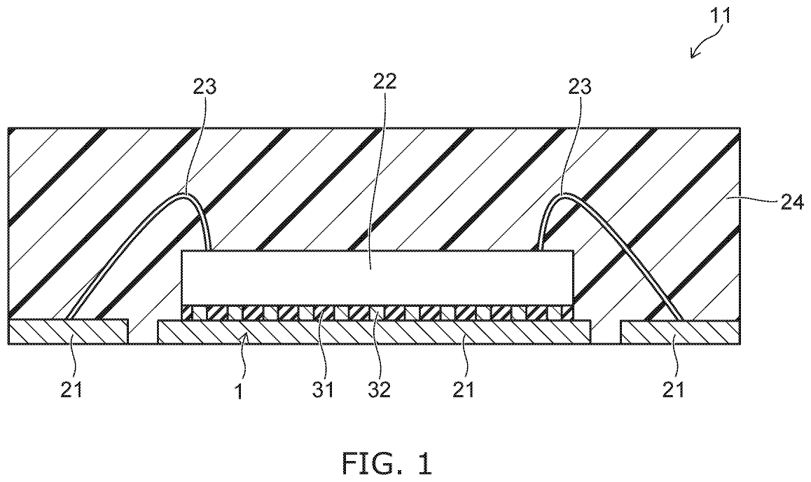

FIG. 1 is a cross-sectional view showing a semiconductor package according to the embodiment.

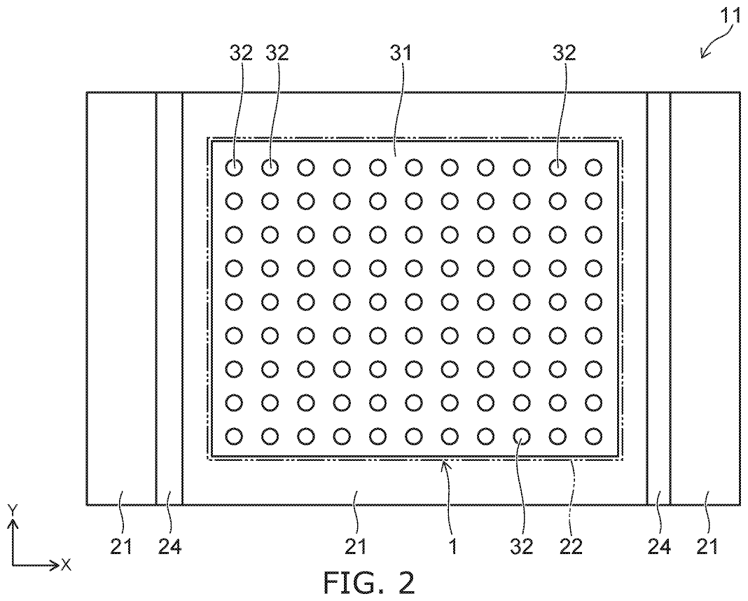

FIG. 2 is a plan view showing the semiconductor package according to the embodiment.

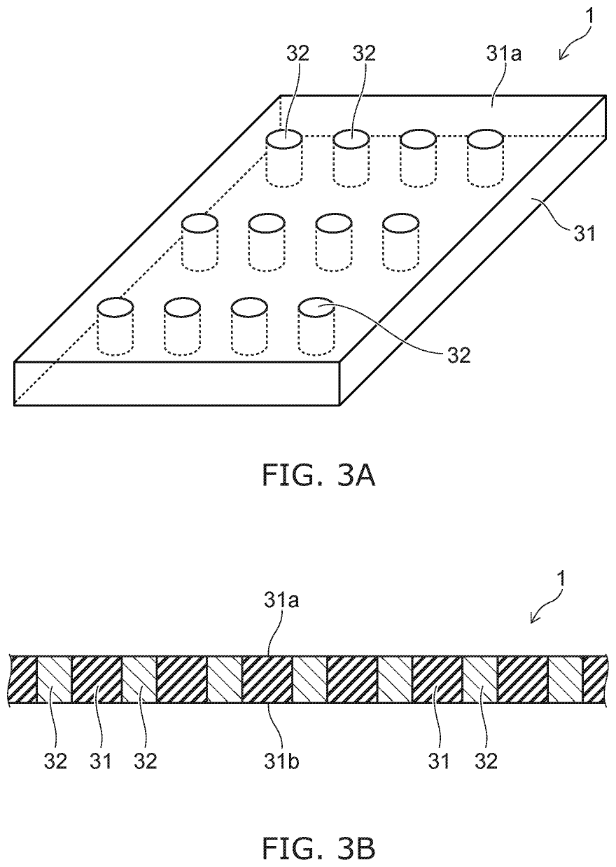

FIG. 3A is a perspective view showing a die attach film according to the embodiment; and FIG. 3B is a cross-sectional view showing the die attach film according to the embodiment.

The drawings are schematic and are drawn with appropriate exaggerations or omissions. The numbers, dimensional ratios, etc., of the components do not always match between the drawings. This is similar for subsequent drawings as well.

As shown in FIG. 1, a leadframe 21, a semiconductor chip 22, a die attach film (DAF) 1, a wire 23, and a resin member 24 are provided in the semiconductor package 11 according to the embodiment.

The leadframe 21 is made of a metal material and is made of, for example, copper or a copper alloy. The leadframe 21 is patterned into a prescribed configuration according to the application of the semiconductor package 11.

The semiconductor chip 22 is disposed on the leadframe 21. For example, the semiconductor chip 22 is a chip in which a relatively large current flows; and the heat generation amount when operating is large. The semiconductor chip 22 is, for example, a power semiconductor chip for power control or an analog semiconductor chip for analog signal processing and is, for example, a motor control chip. Multiple electrodes (not illustrated) are provided in the semiconductor chip 22.

The die attach film 1 is disposed between the leadframe 21 and the semiconductor chip 22. One surface of the die attach film 1 contacts the upper surface of the leadframe 21; and another surface of the die attach film 1 contacts the lower surface of the semiconductor chip 22. The semiconductor chip 22 is bonded to the leadframe 21 by the die attach film 1.

An electrode of the semiconductor chip 22 is connected to the leadframe 21 via the wire 23. The wire 23 forms a loop above the leadframe 21 and the semiconductor chip 22.

The resin member 24 covers the wire 23, the semiconductor chip 22, the die attach film 1, and the side surface and the upper surface of the leadframe 21 and substantially defines the exterior form of the semiconductor package 11. The configuration of the resin member 24 is, for example, a substantially rectangular parallelepiped. In the embodiment, for example, the lower surface of the leadframe 21 is not covered with the resin member 24. The heat dissipation improves thereby. The resin member 24 may cover the entire leadframe 21. The protection from the external atmosphere improves thereby.

As shown in FIG. 2 and FIGS. 3A and 3B, an adhesive layer 31 that has a sheet configuration is provided in the die attach film 1. The adhesive layer 31 is made of a bonding agent and is made of, for example, an epoxy or an acrylic. Multiple posts 32 are provided inside the adhesive layer 31. The posts 32 are made of a material having a thermal conductivity that is higher than the thermal conductivity of the adhesive layer 31 and are made of, for example, a metal such as copper, a copper alloy, etc. In FIG. 2, the semiconductor chip 22 is illustrated by a double dot-dash line; and the wire 23 and the upper portion of the resin member 24 are not illustrated.

The posts 32 have columnar configurations having central axes extending in the thickness direction of the adhesive layer 31 and are, for example, circular columns. However, the posts 32 are not limited to circular columns and may be, for example, elliptical columns, quadrilateral columns, hexagonal prisms, etc. The posts 32 are exposed at a first surface 31a of the adhesive layer 31. The posts 32 also may be exposed at both the first surface 31a and a second surface 31b of the adhesive layer 31. The front and back of the die attach film 1 are arbitrary; the first surface 31a of the adhesive layer 31 may contact the leadframe 21 and the second surface 31b may contact the semiconductor chip 22; or the first surface 31a of the adhesive layer 31 may contact the semiconductor chip 22 and the second surface 31b may contact the leadframe 21.

The posts 32 are arranged periodically along each of two directions parallel to the first surface 31a of the adhesive layer 31, i.e., an X-direction and a Y-direction. For example, the X-direction is orthogonal to the Y-direction. For example, the arrangement interval of the posts 32 in the X-direction is equal to the arrangement interval of the posts 32 in the Y-direction.

Effects of the embodiment will now be described.

In the die attach film 1 according to the embodiment, the posts 32 are provided inside the adhesive layer 31. The thermal conductivity of the posts 32 is higher than the thermal conductivity of the adhesive layer 31. Therefore, the die attach film 1 can bond and fix the semiconductor chip 22 to the leadframe 21 by the adhesive layer 31, and can conduct the heat of the semiconductor chip 22 to the leadframe 21 by the posts 32.

The posts 32 are exposed at least at the first surface 31a of the adhesive layer 31 and are exposed also at, for example, the second surface 31b. Therefore, the thermal resistance is low between the posts 32 and the leadframe 21 and/or between the posts 32 and the semiconductor chip 22. Because the posts 32 have columnar configurations extending in the thickness direction of the adhesive layer 31, the shortest heat transfer path between the two surfaces of the die attach film 1 can be realized by the posts 32. Therefore, the thermal conductivity in the film thickness direction of the die attach film 1 is high. The heat that is generated in the semiconductor chip 22 is conducted in the film thickness direction through the die attach film 1, is conducted to the leadframe 21, and is dissipated outside the semiconductor package 11. Accordingly, the heat dissipation of the semiconductor package 11 is good.

The mechanical structure of the die attach film 1 is stable because the posts 32 that have solid configurations are disposed inside the adhesive layer 31. Conversely, if a paste including a resin material and a noble metal is used instead of the die attach film, the paste may creep up along the side surface of the semiconductor chip 22. If a thin chip is used as the semiconductor chip 22, there is a possibility that the paste may creep up, reach the upper surface of the semiconductor chip 22, and contaminate the upper surface of the semiconductor chip 22. Because the semiconductor package 11 according to the embodiment uses a die attach film as a fixing material to fix the semiconductor chip 22 to the leadframe 21, there is no such risk; and an application to a thin semiconductor chip having a large heat generation amount can be realized favorably.

### First Modification of First Embodiment

A first modification of the embodiment will now be described.

The configuration of a die attach film of the modification is different from that of the first embodiment.

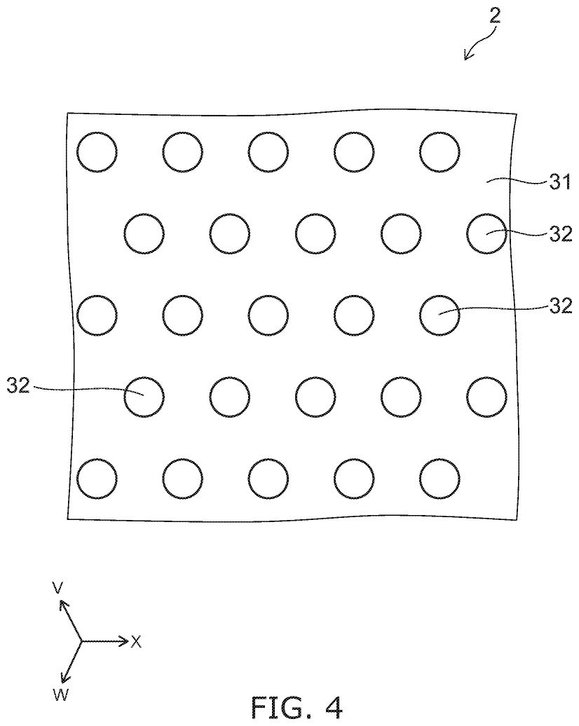

FIG. 4 is a plan view showing the die attach film according to the modification.

In the die attach film 2 according to the modification as shown in FIG. 4, the posts 32 are arranged periodically inside the adhesive layer 31 along three directions, i.e., the X-direction, a V-direction, and a W-direction. For example, the angles between the X-direction, the V-direction, and the W-direction are 120 degrees; and the arrangement intervals of the posts 32 are the same. Thereby, the posts 32 can be arranged two-dimensionally with the maximum packing when the distance between the posts 32 is constant. As a result, the thermal conductivity of the die attach film 2 can be improved further.

Otherwise, the configuration and the effects of the modification are similar to those of the first embodiment.

### Second Modification of First Embodiment

A second modification of the embodiment will now be described.

The configuration of a die attach film of the modification is different from that of the first embodiment.

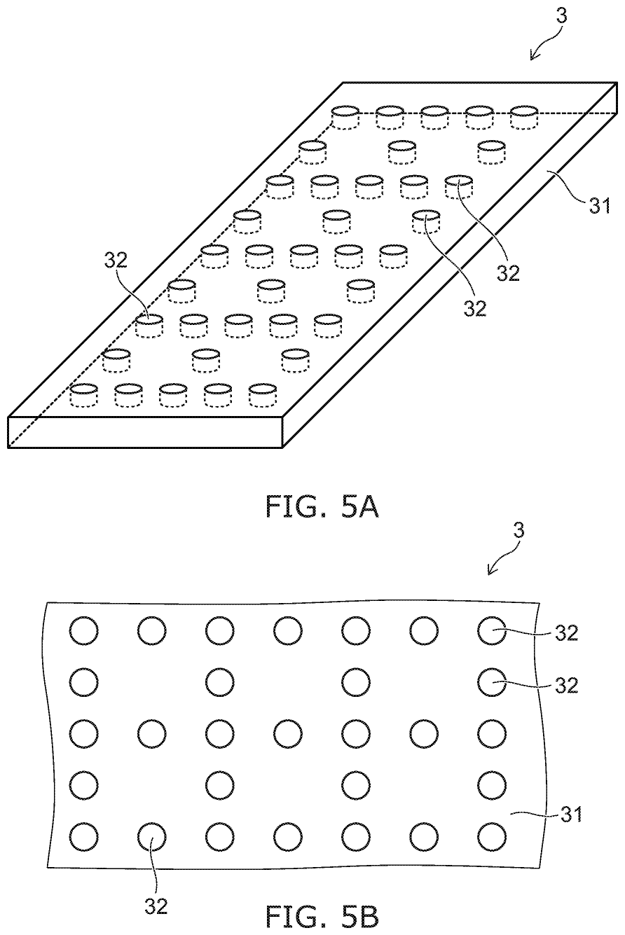

FIG. 5A is a perspective view showing the die attach film according to the modification; and FIG. 5B is a plan view of the die attach film according to the modification.

In the die attach film 3 according to the modification as shown in FIGS. 5A and 5B, the posts 32 are arranged in a lattice configuration pattern inside the adhesive layer 31, As described above, in the die attach film, the adhesive layer 31 performs the adhesion; and the posts 32 perform the thermal conduction. Therefore, in the die attach film, the adhesion increases and the thermal conduction decreases as the proportion of the posts 32 decreases; and the thermal conduction increases and the adhesion decreases as the proportion of the posts 32 increases. As in the modification, the balance between the adhesion and the thermal conduction can be optimized locally in the die attach film 3 by arranging the posts 32 in any pattern.

Also, the thermal expansion coefficient of the die attach film 3 can be controlled by adjusting the arrangement of the posts 32. For example, the thermal expansion coefficient of the die attach film 3 can be set to a value between the thermal expansion coefficient of the leadframe 21 and the thermal expansion coefficient of the semiconductor chip 22. Thereby, the thermal stress that is generated between the leadframe 21 and the semiconductor chip 22 can be relaxed; and the reliability of the semiconductor package can be increased. In such a case as well, the thermal expansion coefficient of the die attach film 3 can be optimized locally by arranging the posts 32 in any pattern. For example, the optimization of the thermal expansion coefficient of the die attach film 3 can be given priority in the high-temperature portions; and the optimization of the balance between the adhesion and the thermal conduction can be given priority in the other portions.

Otherwise, the configuration and the effects of the modification are similar to those of the first embodiment.

### Third Modification of First Embodiment

A third modification of the embodiment will now be described.

The modification is an example in which the arrangement of the posts 32 in the die attach film is optimized to match the semiconductor chip 22.

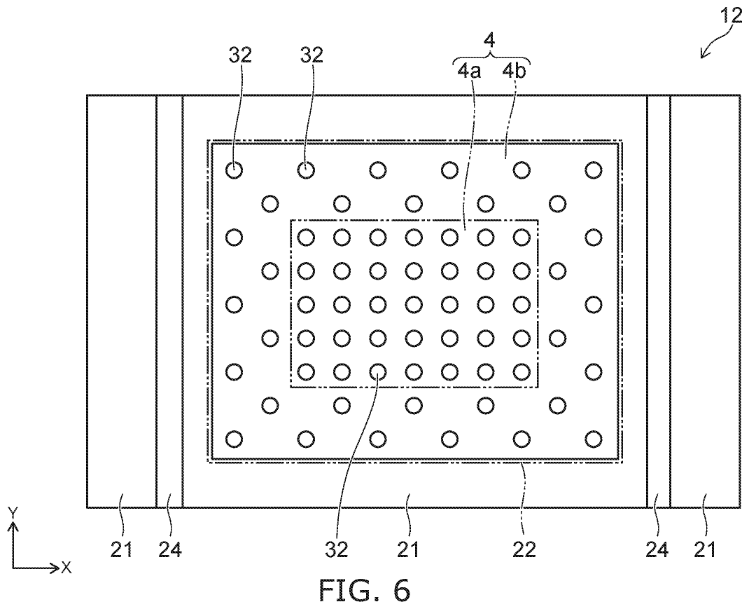

FIG. 6 is a plan view showing a semiconductor package according to the modification.

In FIG. 6, the semiconductor chip 22 is illustrated by a double dot-dash line; and the wire 23 and the upper portion of the resin member 24 are not illustrated.

As shown in FIG. 6, a die attach film 4 is provided in the semiconductor package 12 according to the modification. In the die attach film 4, the proportion of the posts 32 in a first portion 4a is higher than the proportion of the posts 32 in a second portion 4b. The first portion 4a is a portion contacting the central portion of the semiconductor chip 22; and the second portion 4b is a portion contacting the peripheral portion of the semiconductor chip 22. The central portion of the semiconductor chip 22 is a portion that includes the center, e.g., the intersection of the diagonal lines, of the semiconductor chip 22 and does not include the end edge of the semiconductor chip 22 when viewed from above; and the peripheral portion of the semiconductor chip 22 is a portion that includes the end edge of the semiconductor chip 22 and does not include the center of the semiconductor chip 22 when viewed from above. The discrimination between the first portion 4a and the second portion 4b is arbitrary; and a physical boundary may not exist.

In the die attach film 4 of the modification, the proportion of the posts 32 is increased to give priority to the thermal conduction over the adhesion in the first portion 4a contacting the central portion of the semiconductor chip 22 where heat is confined easily; and the proportion of the posts 32 is reduced to give priority to the adhesion over the thermal conduction in the second portion 4b contacting the peripheral portion of the semiconductor chip 22 where peeling starts easily. Thus, by optimizing the balance between the adhesion and the thermal conduction in the die attach film 4 locally according to the semiconductor chip 22, good heat dissipation and strength can be realized for the semiconductor package 12 as an entirety.

Otherwise, the configuration and the effects of the modification are similar to those of the first embodiment.

### Fourth Modification of First Embodiment

A fourth modification of the embodiment will now be described.

The configuration of a die attach film of the modification is different from that of the first embodiment.

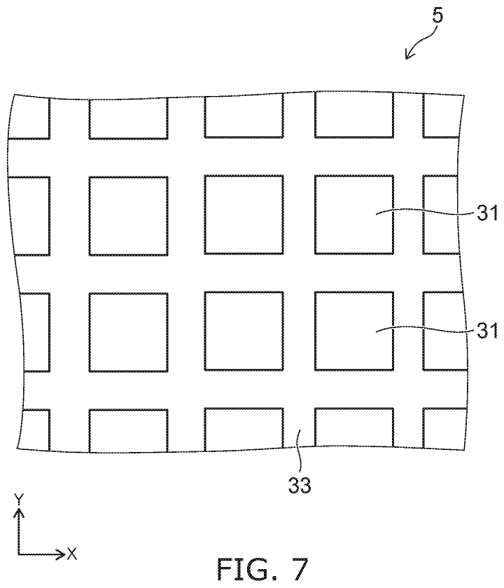

FIG. 7 is a plan view showing the die attach film according to the modification.

As shown in FIG. 7, the adhesive layer 31 and a post 33 are provided in the die attach film 5 according to the modification. The post 33 has a lattice configuration when viewed from the thickness direction of the adhesive layer 31 and includes a portion extending in a straight line in the X-direction and a portion extending in a straight line in the Y-direction. Otherwise, the configuration of the post 33 is similar to the posts 32 of the first embodiment.

Because the post 33 has a lattice configuration in the die attach film 5, the thermal conduction is high not only in the film thickness direction but also in the film surface direction. Therefore, the heat is diffused efficiently also in the film surface direction while being conducted in the film thickness direction; and good heat dissipation as an entirety can be realized.

Otherwise, the configuration and the effects of the modification are similar to those of the first embodiment.

### Second Embodiment

A second embodiment will now be described.

The embodiment is a method for manufacturing the die attach film according to the first embodiment and the modifications of the first embodiment described above.

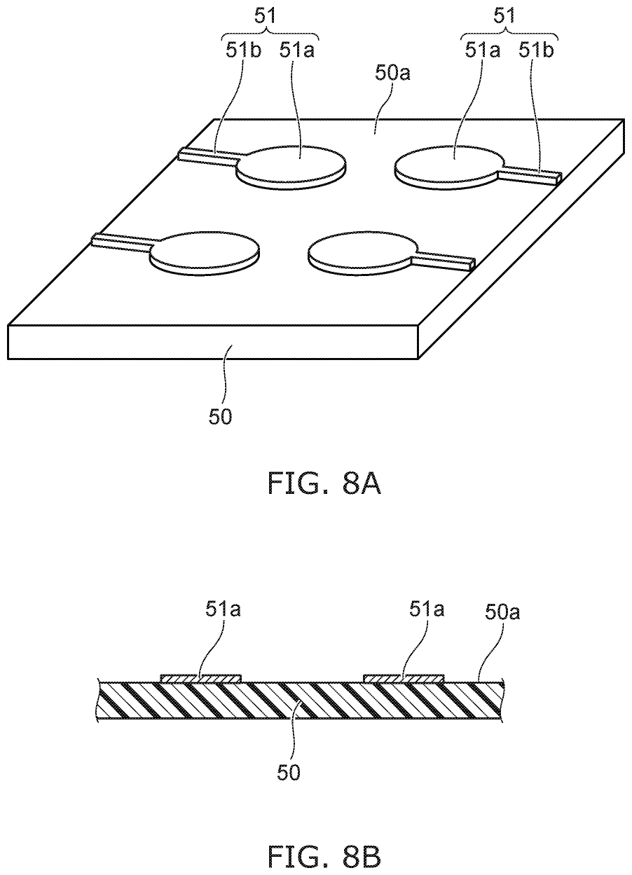

FIG. 8A to FIG. 15B show the method for manufacturing the die attach film according to the embodiment.

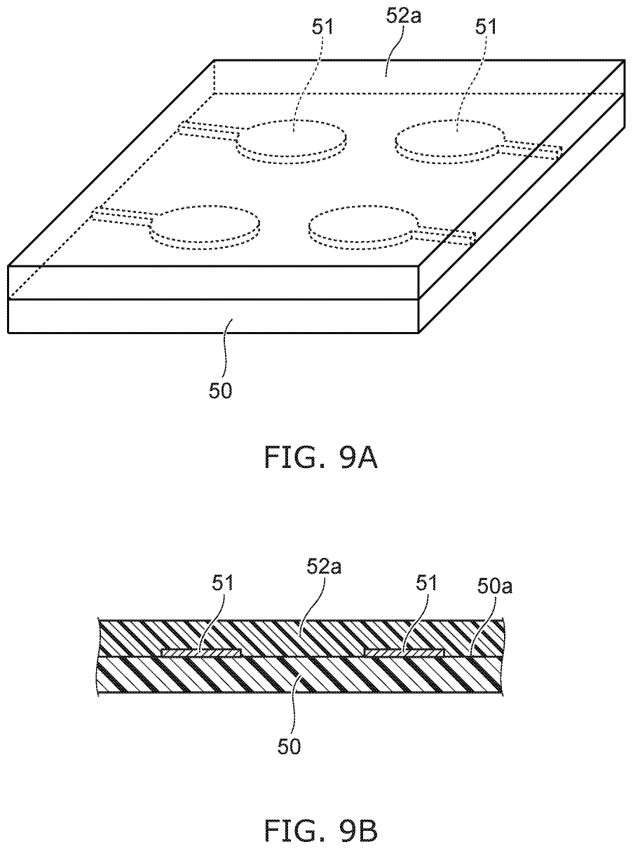

FIG. 8A is a perspective view showing one process; and FIG. 8B is a cross-sectional view showing the same process as FIG. 8A. This is similar for FIG. 9A to FIG. 15B as well.

First, a support sheet 50 is prepared as shown in FIGS. 8A and 8B. The support sheet 50 is an insulating sheet and is, for example, a resin sheet. Then, a seed layer 51 is formed selectively on an upper surface 50a of the support sheet 50. The seed layer 51 is made of a metal and is made of, for example, copper. The seed layer 51 includes a main body portion 51a that is formed in a region where the post 32 is to be formed, and an interconnect portion 51b that is drawn out from the main body portion 51a and connected to a power supply potential. The method for forming the seed layer 51 is not particularly limited; for example, electroless plating may be used; or patterning by lithography may be performed after forming a metal layer on the entire surface by vacuum vapor deposition.

Then, as shown in FIGS. 9A and 9B, a resist film 52a is formed by coating a resist material on the upper surface 50a of the support sheet 50.

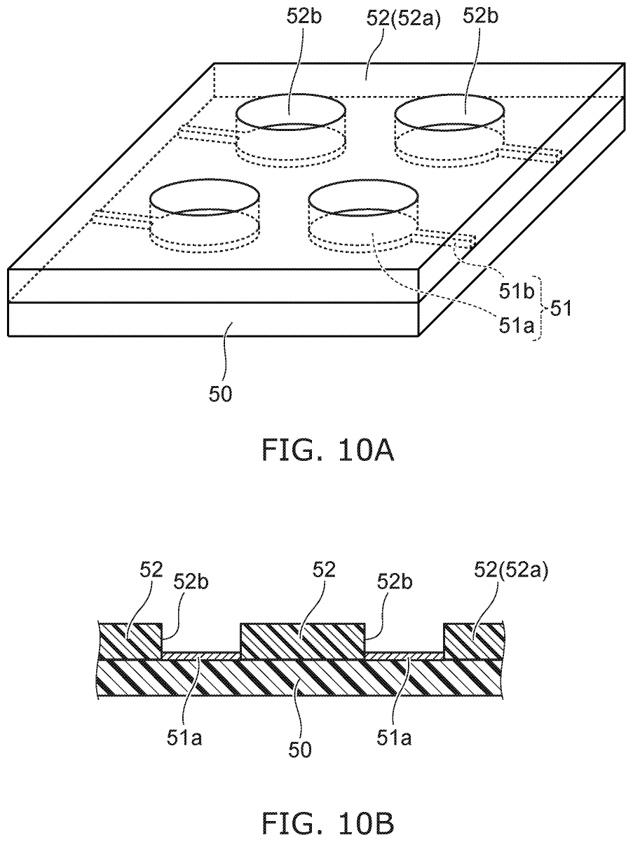

Continuing as shown in FIGS. 10A and 10B, a resist pattern 52 is formed by selectively removing the resist film 52a by, for example, lithography. An opening 52b is formed in the resist pattern 52 in the region directly above the main body portion 51a of the seed layer 51. Thereby, the resist pattern 52 covers the exposed surface of the support sheet 50 and leaves the main body portion 51a of the seed layer 51 exposed.

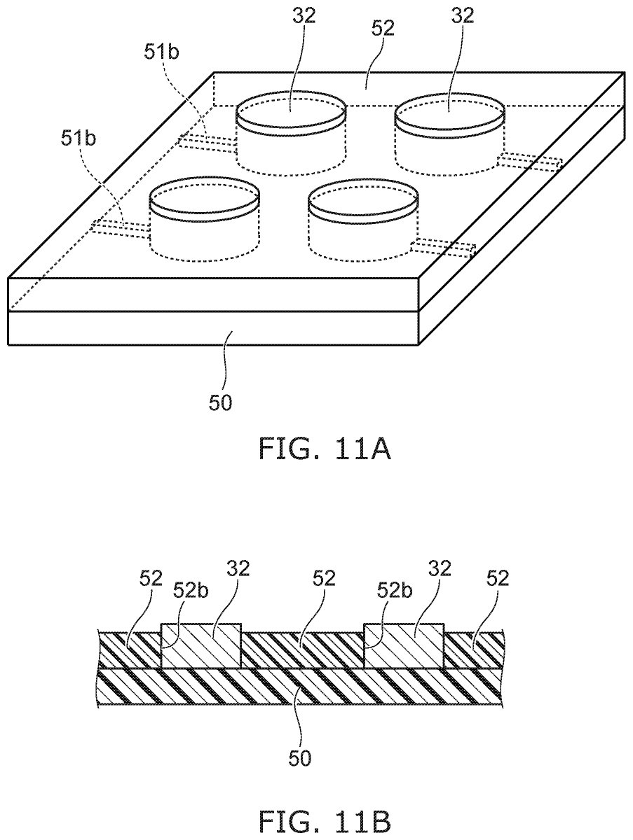

Then, as shown in FIGS. 11A and 11B, a metal, e.g., copper is electroplated on the upper surface of the main body portion 51a by applying a potential to the main body portion 51a by using the interconnect portion 51b of the seed layer 51. Thereby, the post 32 is formed on the main body portion 51a. The main body portion 51a of the seed layer 51 is described as a portion of the post 32 hereinafter.

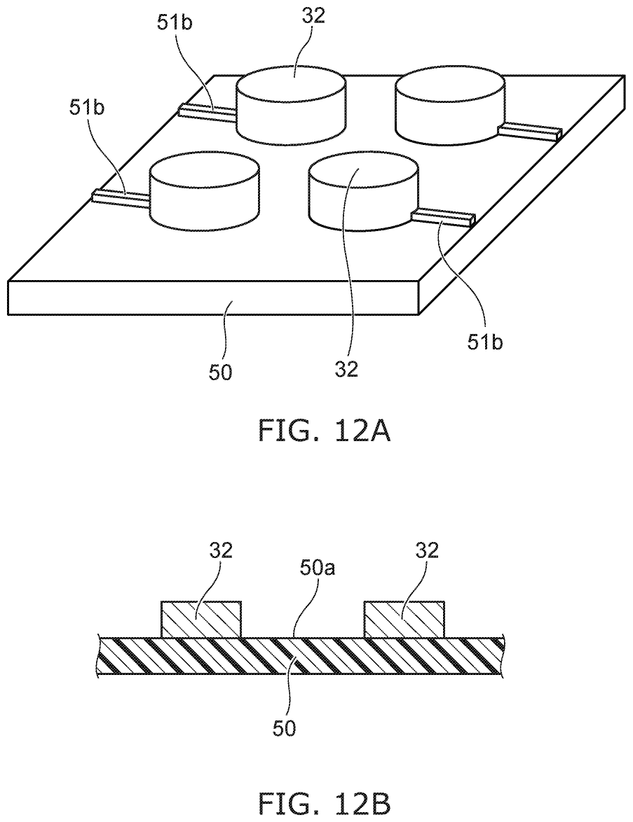

Continuing, the resist pattern 52 (referring to FIGS. 11A and 11B) is removed as shown in FIGS. 12A and 12B.

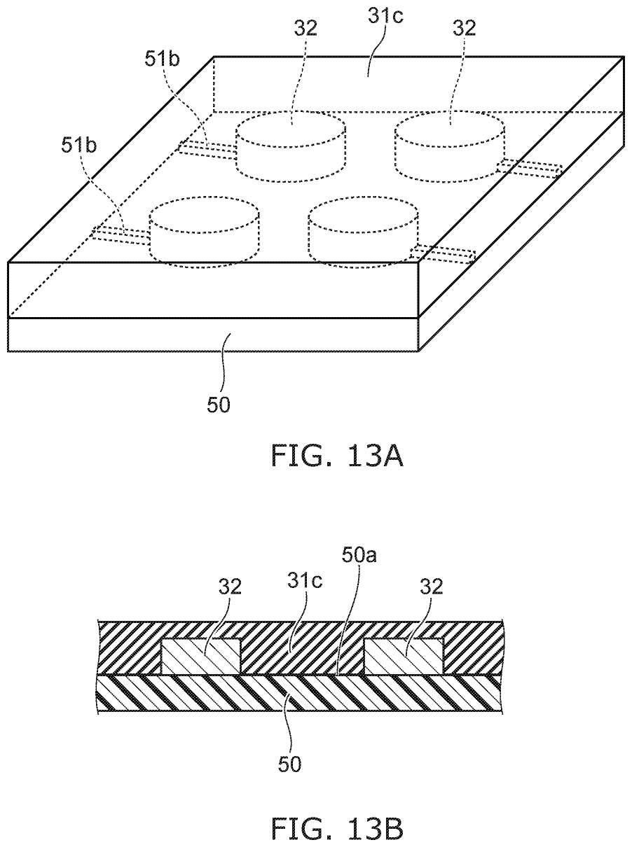

Then, as shown in FIGS. 13A and 13B, an adhesive layer 31c is formed by coating a bonding material on the upper surface 50a of the support sheet 50. At this stage, the adhesive layer 31c covers the entire post 32.

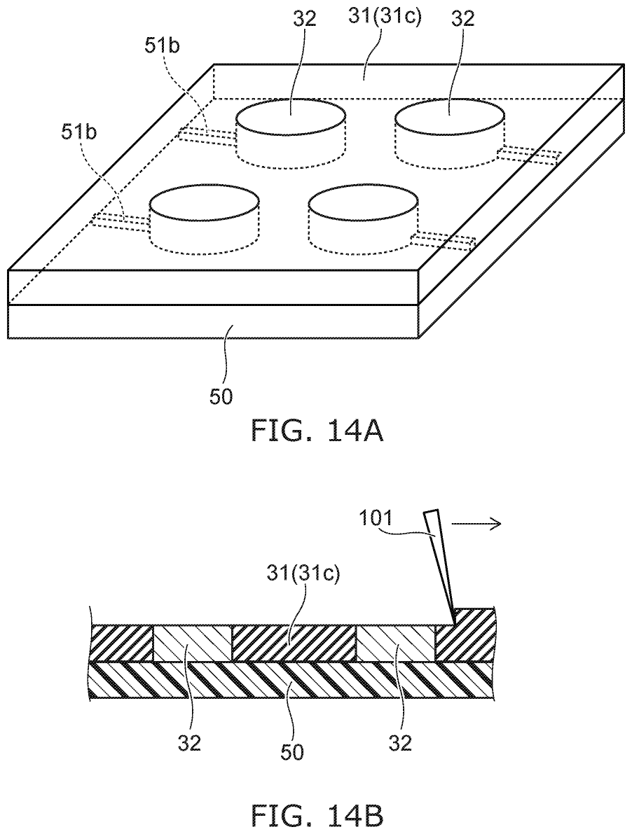

Continuing as shown in FIGS. 14A and 14B, the upper portion of the adhesive layer 31c is removed. For example, the upper portion of the adhesive layer 31c is wiped away by a squeegee 101. Thereby, the upper surface of the post 32 is exposed; and the adhesive layer 31 is formed. The thermal conductivity of the adhesive layer 31 is lower than the thermal conductivity of the post 32. At this stage, the post 32 is exposed at the upper surface (the second surface 31b) of the adhesive layer 31. A thin adhesive layer 31 may remain on the upper surface of the post 32. In such a case, the post 32 is not exposed at the upper surface (the second surface 31b) of the adhesive layer 31.

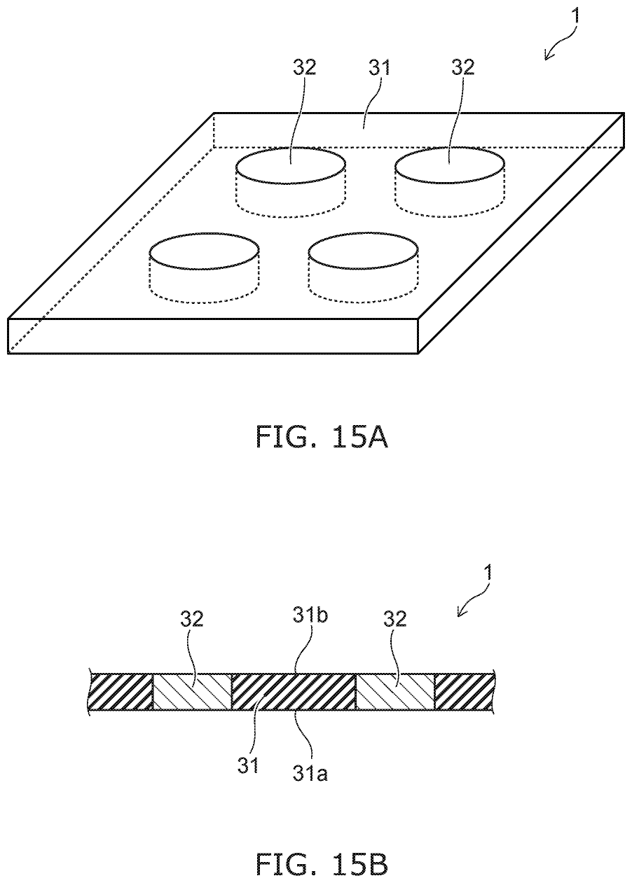

Then, as shown in FIGS. 15A and 15B, the support sheet 50 (referring to FIGS. 14A and 14B) is removed. For example, a chemical in which a dissolution rate of the support sheet 50 that is faster than the dissolution rate of the adhesive layer 31 and the post 32 is caused to contact the support sheet 50; and the support sheet 50 is dissolved from the lower surface side. Thereby, the post 32 is exposed at the lower surface (the first surface 31a) of the adhesive layer 31. At this time, the seed layer 51 may or may not be removed with the support sheet 50. FIGS. 15A and 15B show the case where the seed layer 51 is removed. Thus, the die attach film 1 is manufactured.

Effects of the embodiment will now be described.

According to the embodiment, the posts 32 can be formed at any position in the process shown in FIGS. 11A and 11B because the seed layer 51 can be formed in any layout in the process shown in FIGS. 8A and 8B. Thereby, the arrangement of the posts 32 can be determined freely; and the balance between the adhesion and the thermal conduction of the die attach film 1 can be optimized. For example, uniform adhesion and thermal conduction may be realized for the entire die attach film 1 by arranging the posts 32 periodically. Or, the balance between the adhesion and the thermal conduction may be optimized for each portion by arranging the posts 32 nonuniformly.

According to the embodiment, the posts 32 are formed by the electroplating in the process shown in FIGS. 11A and 11B after forming the seed layer 51 in the process shown in FIGS. 8A and 8B. The posts 32 can be formed efficiently thereby.

To reinforce the die attach film 1, the die attach film 1 may be distributed in a state in which the support sheet 50 remains; and the support sheet 50 may be removed directly before use. Although an example is shown in the embodiment in which the die attach film 1 according to the first embodiment described above is manufactured, this is not limited thereto. For example, the die attach films according to the modifications of the first embodiment also can be manufactured by a similar method. Die attach films that have configurations not described in the first embodiment and the modifications of the first embodiment also can be manufactured by the method according to the embodiment.

### Third Embodiment

A third embodiment will now be described.

The embodiment also is a method for manufacturing the die attach film according to the first embodiment and the modifications of the first embodiment described above.

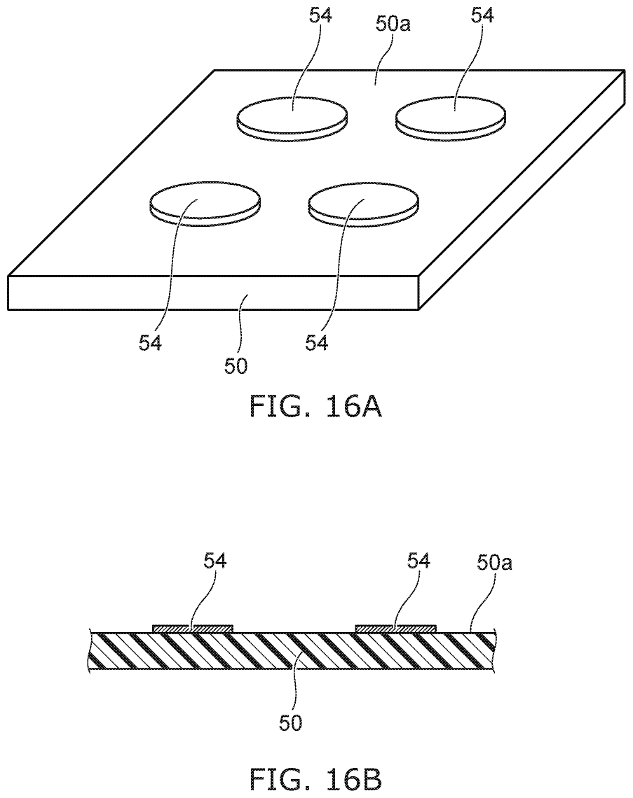

FIG. 16A to FIG. 21B show the method for manufacturing the die attach film according to the embodiment.

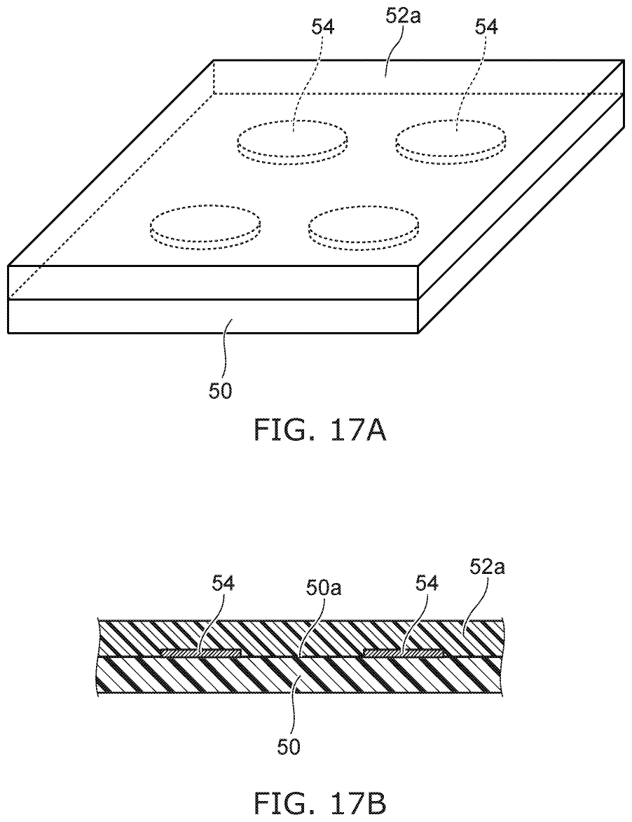

FIG. 16A is a perspective view showing one process; and FIG. 16B is a cross-sectional view showing the same process as FIG. 16A. This is similar for FIG. 17A to FIG. 21B as well.

First, the support sheet 50 is prepared as shown in FIGS. 16A and 16B. The support sheet 50 is an insulating sheet, e.g., a resin sheet. Then, a seed layer 54 is formed selectively on the upper surface 50a of the support sheet 50. The seed layer 54 is made of a metal and is made of, for example, copper. The seed layer 54 is formed in the region where the post 32 is to be formed.

Then, as shown in FIGS. 17A and 17B, the resist film 52a is formed by coating a resist material onto the upper surface 50a of the support sheet 50.

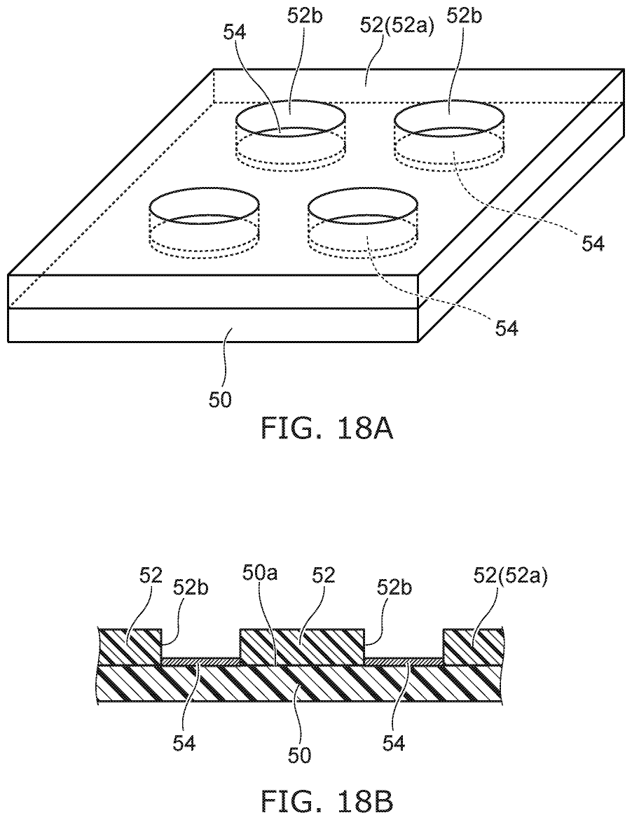

Continuing as shown in FIGS. 18A and 18B, the resist pattern 52 is formed by selectively removing the resist film 52a by, for example, lithography. The opening 52b is formed in the resist pattern 52 in the region directly above the seed layer 54. Thereby, the resist pattern 52 covers the exposed surface of the support sheet 50 and leaves the seed layer 54 exposed.

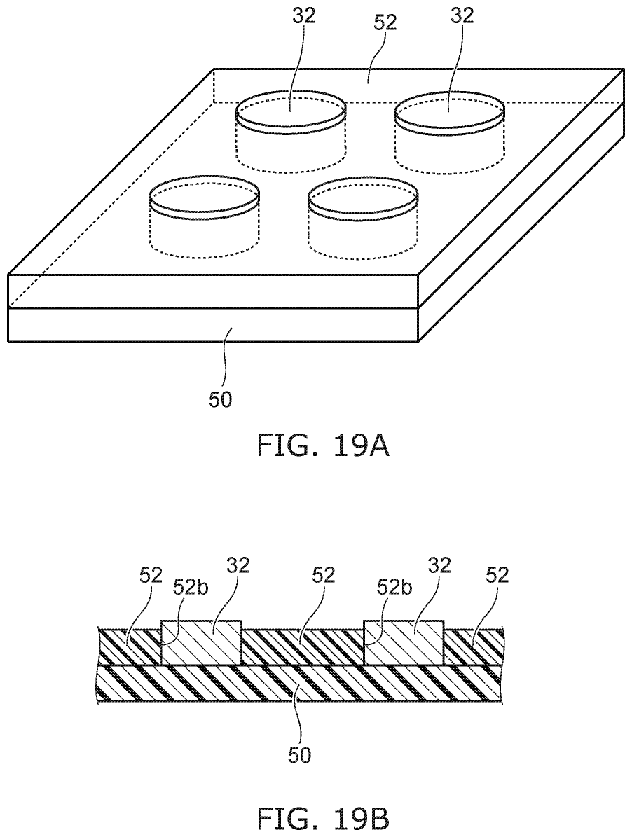

Then, as shown in FIGS. 19A and 19B, electroless plating of a metal, e.g., copper is performed inside the opening 52b, that is, on the upper surface of the seed layer 54. The post 32 is formed on the seed layer 54 thereby. The seed layer 54 is described as a portion of the post 32 hereinafter.

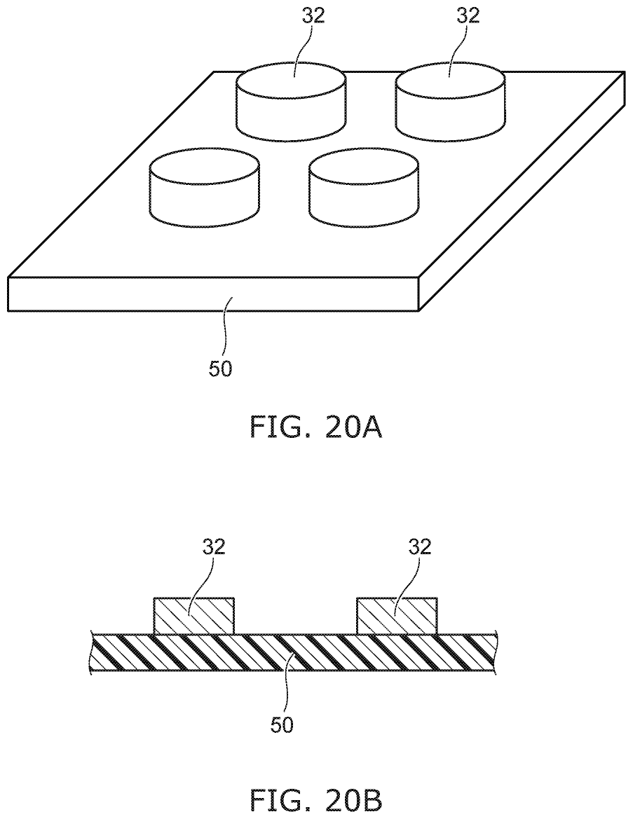

Continuing as shown in FIGS. 20A and 20B, the resist pattern 52 (referring to FIGS. 19A and 19B) is removed.

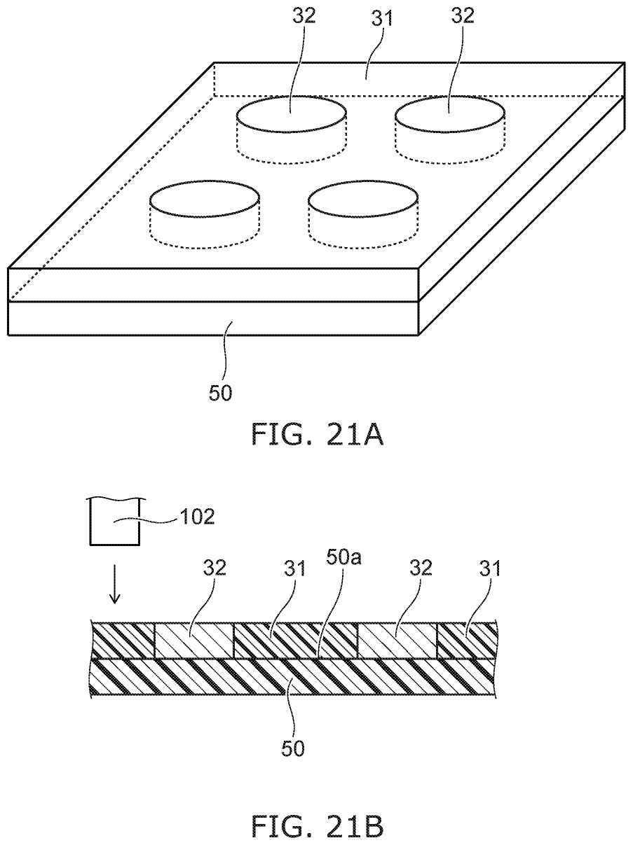

Then, as shown in FIGS. 21A and 21B, a bonding material is coated onto the upper surface 50a of the support sheet 50 by, for example, a nozzle 102, The bonding material is filled between the posts 32. The adhesive layer 31 is formed thereby.

Continuing, the support sheet 50 is removed by performing a process similar to FIGS. 15A and 15B. Thus, the die attach film 1 is manufactured.

Effects of the embodiment will now be described.

In the embodiment, the posts 32 are formed by electroless plating in the process shown in FIGS. 19A and 19B. Therefore, it is unnecessary to form the interconnect portions when forming the seed layer 54 in the process shown in FIGS. 16A and 16B. Thereby, the seed layer 54 can be arranged with high density; and the posts 32 can be arranged with high density.

Otherwise, the manufacturing method and the effects of the embodiment are similar to those of the second embodiment.

### Fourth Embodiment

A fourth embodiment will now be described.

The embodiment also is a method for manufacturing the die attach film according to the first embodiment and the modifications of the first embodiment described above.

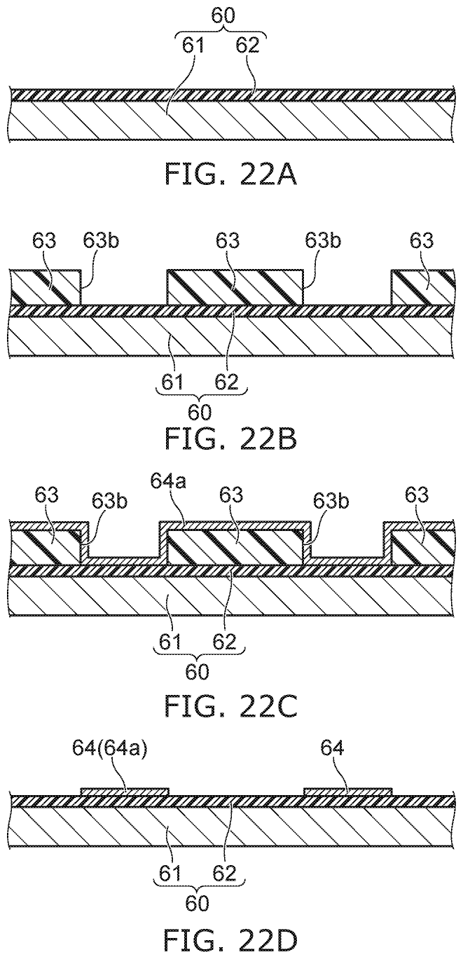

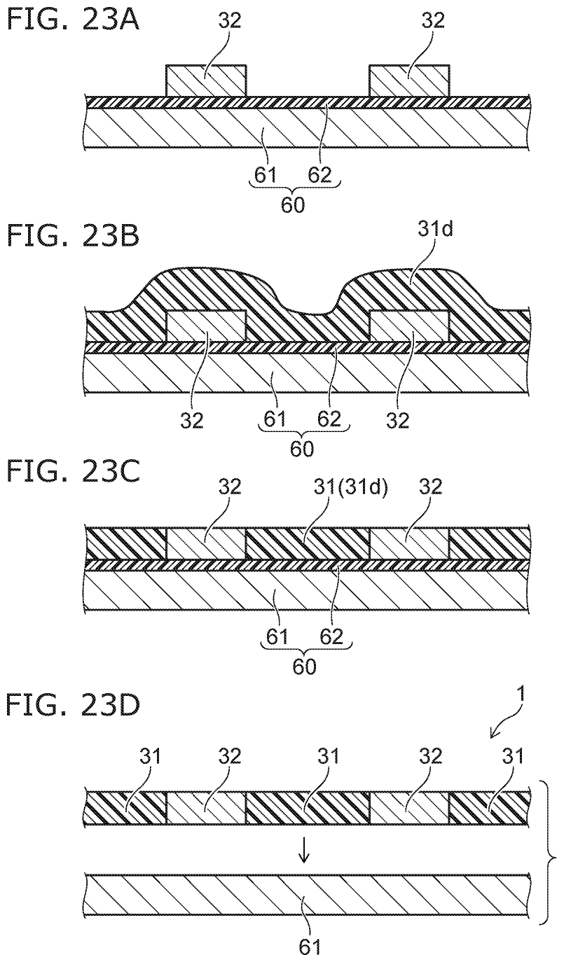

FIGS. 22A to 22D and FIGS. 23A to 23D are cross-sectional views showing the method for manufacturing the die attach film according to the embodiment.

First, a support sheet 60 is prepared as shown in FIG. 22A. In the support sheet 60, for example, a resin tape 62 is bonded to a main material 61 made of a metal. The resin tape 62 is made of a resin material and is made of, for example, polyimide.

Then, as shown in FIG. 22B, a resist pattern 63 is formed on the resin tape 62 of the support sheet 60 by lithography. An opening 63b is formed in the resist pattern 63 in the region where the post 32 is to be formed.

Continuing as shown in FIG. 22C, a metal layer 64a is formed on the entire surface by, for example, electroless plating or vapor deposition such as vacuum vapor deposition, sputtering, etc.

Then, the resist pattern 63 is removed as shown in FIG. 22D. At this time, the portion of the metal layer 64a formed on the surface of the resist pattern 63 is removed with the resist pattern 63. On the other hand, the portion of the metal layer 64a formed on the resin tape 62 inside the opening 63b of the resist pattern 63 remains to become a seed layer 64.

Continuing as shown in FIG. 23A, the post 32 is formed by depositing a metal, e.g., copper on the seed layer 64 by electroplating. The seed layer 64 is described as a portion of the post 32 hereinafter.

Then, as shown in FIG. 23B, a bonding film 31d is bonded to the resin tape 62 to cover the post 32. At this time, a protrusion that reflects the post 32 appears at the upper surface of the resin tape 62.

Continuing as shown in FIG. 23C, the upper surface of the post 32 is exposed by removing the upper portion of the bonding film 31d, For example, a protrusion that reflects the post 32 is removed by polishing the upper surface of the bonding film 31d. Thereby, the bonding film 31d remains between the posts 32 and becomes the adhesive layer 31.

Then, as shown in FIG. 23D, the resin tape 62 is removed by, for example, dissolving in a chemical liquid. Thereby, the support sheet 60 is removed by peeling the main material 61 from the adhesive layer 31 and the post 32. Thus, the die attach film 1 is manufactured.

According to the embodiment as well, the die attach film according to the first embodiment and the modifications of the first embodiment can be manufactured.

Otherwise, the manufacturing method and the effects of the embodiment are similar to those of the second embodiment.

A method for forming the adhesive layer 31 by printing using a squeegee is described in the second embodiment; a method for forming the adhesive layer 31 by coating using a nozzle is described in the third embodiment; and a method for forming the adhesive layer 31 by laminating to bond a bonding film is described in the fourth embodiment; but the combination of the embodiments and the methods of forming the adhesive layer 31 are arbitrary. The combinations of the embodiments and the methods for removing the support sheet also are arbitrary.

### Fifth Embodiment

A fifth embodiment will now be described.

The embodiment also is a method for manufacturing the die attach film according to the first embodiment and the modifications of the first embodiment described above.

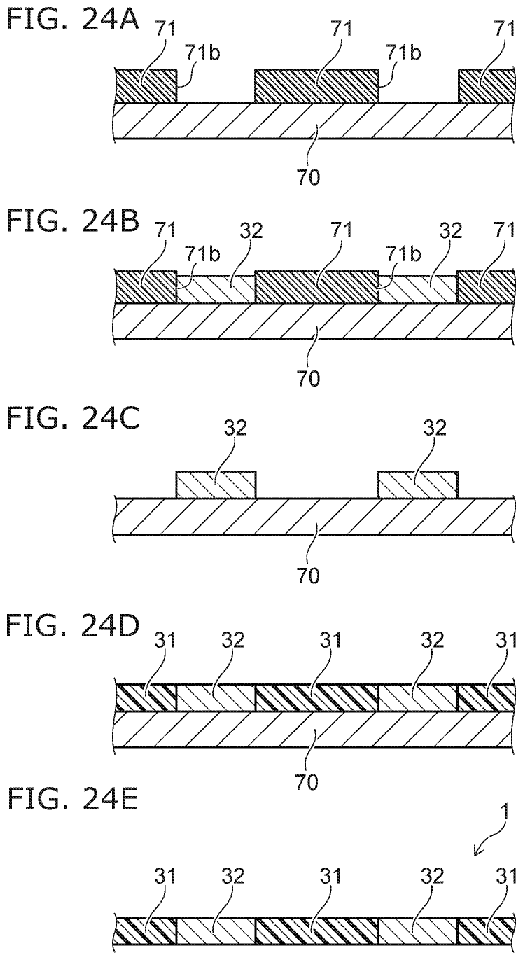

FIGS. 24A to 24E are cross-sectional views showing the method for manufacturing the die attach film according to the embodiment.

First, an electrically conductive support sheet 70 is prepared as shown in FIG. 24A. It is favorable for the support sheet 70 to be formed of a metal or an alloy that is different from the post 32. Then, a resist pattern 71 is formed on the support sheet 70. An opening 71b is formed in the resist pattern 71 in the region where the post 32 is to be formed.

Then, as shown in FIG. 24B, electroplating of a metal, e.g., copper is performed on the upper surface of the support sheet 70 by applying a potential via the support sheet 70. At this time, the metal is deposited only on the exposed surface of the support sheet 70 and is not deposited on the surface of the resist pattern 71. Thereby, the post 32 is formed inside the opening 71b of the resist pattern 71 on the support sheet 70.

Continuing, the resist pattern 71 is removed as shown in FIG. 24C.

Then, as shown in FIG. 24D, the adhesive layer 31 is formed between the posts 32. For example, any method described in the second to fourth embodiments described above is used to form the adhesive layer 31.

Continuing as shown in FIG. 24E, the support sheet 70 is removed by, for example, dissolving the support sheet 70 by a chemical liquid. At this time, only the support sheet 70 can be selectively removed while causing the post 32 to remain by setting the material of the support sheet 70 and the material of the post 32 to be different and by using a chemical liquid in which the dissolution rate of the support sheet 70 is faster than the dissolution rate of the post 32.

Effects of the embodiment will now be described.

According to the embodiment, the die attach film can be manufactured efficiently because the posts 32 can be formed by electroplating without forming a seed layer.

Otherwise, the manufacturing method and the effects of the embodiment are similar to those of the second embodiment.

### Sixth Embodiment

A sixth embodiment will now be described.

The embodiment is an example in which the die attach film is formed directly on a leadframe.

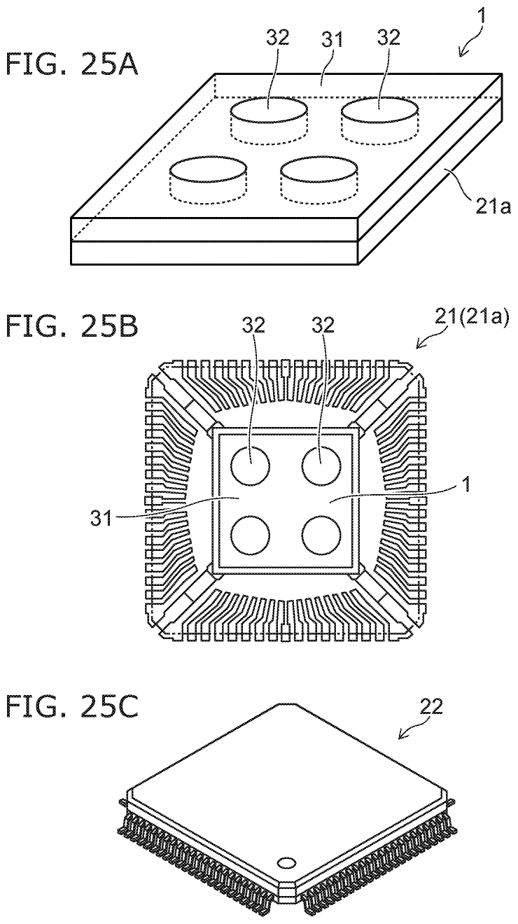

FIGS. 25A to 25C show a method for manufacturing a semiconductor package according to the embodiment.

As shown in FIG. 25A, the die attach film 1 is formed on an original sheet 21a of the leadframe 21. For example, the die attach film 1 is formed on the original sheet 21a by using the original sheet 21a of the leadframe 21 as the support sheet 70 in the process shown in FIGS. 24A to 24D.

Then, as shown in FIG. 25B, the leadframe 21 is formed by patterning the original sheet 21a in a prescribed configuration.

Continuing as shown in FIG. 25C, the semiconductor chip 22 is prepared. Then, the semiconductor chip 22 is bonded to the die attach film 1. Then, the adhesive layer 31 is cured by performing heat treatment. Thus, the semiconductor chip 22 is fixed to the leadframe 21 by the die attach film 1.

Then, as shown in FIG. 1, the wire 23 is connected between the leadframe 21 and the semiconductor chip 22 by performing wire bonding. Then, the resin member 24 that seals the wire 23, the semiconductor chip 22, the die attach film 1, and at least a portion of the leadframe 21 is formed by molding a resin material. Thus, the semiconductor package can be manufactured.

According to the embodiment, in the case where multiple semiconductor chips 22 are mounted on one leadframe 21, the arrangement of the posts 32 in the die attach film 1 can be optimized for each semiconductor chip 22.

Otherwise, the configuration and the effects of the embodiment are similar to those of the first embodiment.

Although an example is shown in the embodiments described above in which the post 32 is formed of a metal, this is not limited thereto; for example, an inorganic material or an organic material may be used as long as the thermal conductivity of the material of the post 32 is higher than the thermal conductivity of the adhesive layer 31. For example, the post 32 may be formed of aluminum nitride (AlN).

According to the embodiments described above, a semiconductor package, a die attach film, and a method for manufacturing the die attach film can be realized in which the heat dissipation is good.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Additionally, the embodiments described above can be combined mutually.

What is claimed is:

1. A method for manufacturing a die attach film, comprising:
forming a plurality of posts on a support sheet;
forming an adhesive layer between the posts, a thermal conductivity of the adhesive layer being lower than a thermal conductivity of the posts; and
removing the support sheet.

2. The method according to claim 1, wherein the posts include a metal.

3. The method according to claim 2, wherein the metal is copper.

4. The method according to claim 2, wherein the forming of the posts includes electroplating the metal.

5. The method according to claim 4, wherein
the support sheet is insulative,
the forming of the posts further includes selectively forming a seed layer on the support sheet, the seed layer being connected to a power supply potential, and
the electroplating is performed using the seed layer.

6. The method according to claim 5, wherein
the forming of the posts further includes:
forming a resist pattern before the electroplating, the resist pattern covering the support sheet and leaving the seed layer exposed; and
removing the resist pattern after the electroplating.

7. The method according to claim 2, wherein
the forming of the posts includes:
selectively forming a seed layer on the support sheet;
forming a resist pattern covering the support sheet and leaving the seed layer exposed;
performing electroless plating of the metal on the seed layer; and
removing the resist pattern.

8. The method according to claim 2, wherein
the support sheet includes a main material and a resin tape, the resin tape being provided on the main material,
the forming of the posts includes:
forming a mask pattern on the resin tape, an opening being formed in the mask pattern;
forming a metal layer on the resin tape and on the mask pattern;
removing the mask pattern and removing the metal layer formed on the mask pattern; and
performing electroplating of the metal using a remaining portion of the metal layer as a seed layer, and
the removing of the support sheet includes removing the resin tape.

9. The method according to claim 1, wherein
the forming of the adhesive layer includes:
disposing a bonding material on the support sheet to cover the posts, and
exposing upper surfaces of the posts by using a squeegee on the bonding material.

10. The method according to claim 1, wherein
the forming of the adhesive layer includes:
stacking a bonding film on the support sheet and the plurality of posts; and
exposing upper surfaces of the posts by removing an upper portion of the bonding film.

11. A die attach film, comprising:
an adhesive layer; and
a plurality of posts provided inside the adhesive layer and exposed at a first surface of the adhesive layer, a thermal conductivity of the plurality of posts being higher than a thermal conductivity of the adhesive layer.

12. The film according to claim 11, wherein the posts are exposed also at a second surface of the adhesive layer.

13. The film according to claim 11, wherein the posts have columnar configurations having central axes extending in a thickness direction of the adhesive layer.

14. The film according to claim 11, wherein the posts have a lattice configuration when viewed from a thickness direction of the adhesive layer.

15. The film according to claim 11, wherein the plurality of posts is arranged periodically.

16. The film according to claim 11, wherein the posts include a metal.

17. The film according to claim 16, wherein the metal is copper.

18. A semiconductor package, comprising:
a leadframe;
a semiconductor chip;
the die attach film according to claim 11 contacting the leadframe and the semiconductor chip and fixing the semiconductor chip to the leadframe; and
a resin member covering the die attach film, the semiconductor chip, and at least a portion of the leadframe.

19. The package according to claim 18, wherein a proportion of the posts in a first portion of the die attach film is higher than a proportion of the posts in a second portion of the die attach film, the first portion contacting a central portion of the semiconductor chip, the second portion contacting a peripheral portion of the semiconductor chip.
